(19) United States
(12) Patent Application Publication
(10) Pub. No.: US 2025/0081525 A1
(43) Pub. Date: Mar. 6, 2025

(54) Via To Avoid Local Interconnect Shorting

(71) Applicant: INTERNATIONAL BUSINESS MACHINES CORPORATION, ARMONK, NY (US)

(72) Inventors: Ruilong Xie, Niskayuna, NY (US); James P. Mazza, Saratoga Springs, NY (US); Shahrukh Khan, Sandy Hook, CT (US); Iqbal Rashid Saraf, Glenmont, NY (US); Biswanath Senapati, Mechanicville, NY (US); Tenko Yamashita, Schenectady, NY (US)

(21) Appl. No.: 18/459,012

(22) Filed: Aug. 30, 2023

(51) Int. Cl. H01L 29/417; H01L 21/8234; H01L 23/48; H01L 27/088; H01L 29/06; H01L 29/423; H01L 29/66; H01L 29/775; H01L 29/786

(52) U.S. Cl. CPC H10D 30/6729; H01L 23/481; H10D 30/014; H10D 30/43; H10D 30/6735; H10D 30/6757; H10D 62/121; H10D 84/013; H10D 84/0149; H10D 84/038; H10D 84/83

(57) ABSTRACT

A semiconductor device includes a first source/drain region connected to a back end of line (BEOL) through a first contact and a first via, and a second source/drain region connected to the BEOL through a second contact, a lateral contact, and a second via. The first via passes through the lateral contact.

### BACKGROUND

### Technical Field

The present disclosure generally relates to transistors, and more particularly, to via formation in transistors structure, and methods of creation thereof.

### Description of the Related Art

Backside contacts provide a way to establish electrical connections with the backside or substrate of a transistor and enable efficient signal transmission, improved device performance, and enhanced manufacturing processes. In a typical transistor structure, the backside or substrate region is distinct from the active region where the transistor's channel and source/drain regions are located. The electrical connection established by the backside contacts provides a pathway for electrical signals, current, and voltage to flow, allowing communication between different components of an integrated circuit.

### SUMMARY

According to an embodiment, a semiconductor device includes a first source/drain region connected to a back end of line (BEOL) through a first contact and a first via, and a second source/drain region connected to the BEOL through a second contact, a lateral contact and a second via. The first via passes through the lateral contact, and the first source/drain region is formed over the second source/drain region.

In some embodiments, which can be combined with the previous embodiment, the lateral contact is located above the first and second source/drain regions.

In some embodiments, which can be combined with one or more previous embodiments, the semiconductor device includes a first transistor stacked over a second transistor. The first and second source/drain regions are located on the first and the second transistors, respectively.

In some embodiments, which can be combined with one or more previous embodiments, the second contact further includes a horizontally extended portion over the second source/drain region, and a vertically extended portion connecting the horizontally extended portion to the lateral contact.

In some embodiments, which can be combined with one or more previous embodiments, the semiconductor device includes a first isolation layer covering the first via. A portion of the first isolation layer is connected to the lateral contact.

In some embodiments, which can be combined with one or more previous embodiments, the first isolation layer isolates the first via from direct contact with the lateral contact.

In some embodiments, which can be combined with one or more previous embodiments, the semiconductor device includes a gate via connecting a gate region to the BEOL.

In some embodiments, which can be combined with one or more previous embodiments, a location of the second via is offset from a centerline of the second source/drain region away from the gate region.

In some embodiments, which can be combined with one or more previous embodiments, the semiconductor device includes a second isolation layer covering the gate via. The second isolation layer-covered gate via passes through the lateral contact and the first and second contacts.

In some embodiments, which can be combined with one or more previous embodiments, the second isolation layer isolates the gate via from direct contact with the lateral contact.

According to another embodiment, a method for forming a semiconductor device includes forming a first and a second source/drain region, forming a first and a second contact for the first and the second source/drain region, respectively, forming a lateral contact over the second contact, forming a first contact via for the first source/drain region, and forming a first isolation layer covering the first contact via. The first source/drain region is formed over the second source/drain region.

In some embodiments, which can be combined with the previous embodiment, the lateral contact is located above the first and second source/drain regions, and the first isolation layer isolates the first contact via from direct contact with the lateral contact.

In some embodiments, which can be combined with one or more previous embodiments, a first level metal layer, a second contact via for the second source/drain region, and a second isolation layer covering the second contact via are formed.

In some embodiments, which can be combined with one or more previous embodiments, the first level metal layer is connected to the lateral contact through the second contact via.

In some embodiments, which can be combined with one or more previous embodiments, a gate contact via, a third isolation layer covering the gate contact via, a first and second contact metallization, and a gate contact via metallization are formed. A portion of the third isolation layer is connected to the lateral contact.

In some embodiments, which can be combined with one or more previous embodiments, the second contact has a larger height than the first contact.

In some embodiments, which can be combined with one or more previous embodiments, a first transistor is formed that is stacked over a second transistor. The first and second source/drain regions are located on the first and the second transistors, respectively.

In some embodiments, which can be combined with one or more previous embodiments, a location of the second via is offset from a centerline of the second source/drain region away from a gate region.

In some embodiments, which can be combined with one or more previous embodiments, a horizontally extended portion over the second source/drain region, and a vertically extended portion connecting the horizontally extended portion to the lateral contact are formed.

According to yet another embodiment, a semiconductor device includes a source/drain via connecting a source/drain region to a back end of line (BEOL), and a gate via connecting a gate region to the BEOL. The gate via and the source/drain via are isolated from direct contact with the lateral contact through a first and a second dielectric isolation layer formed over the source/drain via and the gate via, respectively.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate a semiconductor device, in accordance with some embodiments.

FIG. 1D illustrates a top view of a semiconductor device, in accordance with some embodiments.

FIGS. 2A-2C illustrate side-views of a semiconductor device after the processing of the front end of line (FEOL), in accordance with some embodiments.

FIGS. 3A-3C illustrate side-views of a semiconductor device after the formation of the horizontally extended portion of the second contact, in accordance with some embodiments.

FIGS. 4A-4C illustrate side-views of a semiconductor device after the patterning of the source/drain contact, in accordance with some embodiments.

FIGS. 5A-5C illustrate side-views of a semiconductor device after the formation of the deep contact, and the inner spacer is formed, in accordance with some embodiments.

FIGS. 6A-6C illustrate side-views of a semiconductor device after the formation of the lateral contact, in accordance with some embodiments.

FIGS. 7A-7C illustrate side-views of a semiconductor device after the patterning of the first via and gate via, in accordance with some embodiments.

FIGS. 8A-8C illustrate side-views of a semiconductor device after the formation of the spacer, in accordance with some embodiments.

FIGS. 9A-9C illustrate side-views of a semiconductor device after the metallization of the first via and the gate via, in accordance with some embodiments.

FIGS. 10A-10C illustrate side-views of a semiconductor device after the wafer bonding, in accordance with some embodiments.

FIGS. 11A-11C illustrate side-views of a semiconductor device after the formation of the backside interconnect, in accordance with some embodiments.

FIGS. 12A-12B illustrate block diagrams of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

According to an embodiment, a semiconductor device includes a first source/drain region connected to a back end of line (BEOL) through a first contact and a first via, and a second source/drain region connected to the BEOL through a second contact, a lateral contact and a second via. The first via passes through the lateral contact. The first source/drain region is formed over the second source/drain region. Thus, the first source/drain region is connected to the BEOL through the first via.

In some embodiments, which can be combined with the previous embodiment, the lateral contact is located above the first and second source/drain regions. Thus, the lateral contact can be closer to the BEOL than the first and second source/drain regions.

In some embodiments, which can be combined with one or more previous embodiments, the semiconductor device includes a first transistor stacked over a second transistor. The first and second source/drain regions are located on the first and the second transistors, respectively. Thus, the semiconductor device can be used to connect stacked transistors to a common BEOL.

In some embodiments, which can be combined with one or more previous embodiments, the second contact further includes a horizontally extended portion over the second source/drain region, and a vertically extended portion connecting the recessed contact to the lateral contact. The vertically extended portion includes a smaller thickness compared to the horizontally extended portion. Thus, the second contact requires less space, which can decrease the risk of shorting.

In some embodiments, which can be combined with one or more previous embodiments, the semiconductor device includes a first isolation layer covering the first via. A portion of the first isolation layer is connected to the lateral contact. Thus, the first via is isolated from other elements.

In some embodiments, which can be combined with one or more previous embodiments, the first isolation layer isolates the first via from direct contact with the lateral contact. Thus, the risk of lateral contact-first via shorting is decreased.

In some embodiments, which can be combined with one or more previous embodiments, the semiconductor device includes a gate via connecting a gate region to the BEOL. Thus, the gate region is connected to the BEOL.

In some embodiments, which can be combined with one or more previous embodiments, a location of the second via is offset from a centerline of the second source/drain region away from the gate region. Thus, the risk of metal shorting is decreased.

In some embodiments, which can be combined with one or more previous embodiments, the semiconductor device includes a second isolation layer covering the gate via. The second isolation layer-covered gate via passes through the lateral contact and the first and second contacts. Thus, there is no direct contact between the first contact, the second contact and the via contact.

In some embodiments, which can be combined with one or more previous embodiments, the second isolation layer isolates the gate via from direct contact with the lateral contact. Thus, the risk of gate via-lateral contact is decreased.

According to another embodiment, a method for forming a semiconductor device includes forming a first and a second source/drain region, forming a first and a second contact for the first and the second source/drain region, respectively, forming a lateral contact over the second contact, forming a first contact via for the first source/drain region, and forming a first isolation layer covering the first contact via. The first source/drain region is formed over the second source/drain region. Thus, the risk of metal shorting is decreased.

In some embodiments, which can be combined with the previous embodiment, the lateral contact is located above the first and second source/drain regions, and the first isolation layer isolates the first contact via from direct contact with the lateral contact. Thus, the risk of first contact via-lateral contact shorting is decreased.

In some embodiments, which can be combined with one or more previous embodiments, a first level metal layer, a second contact via for the second source/drain region, and a second isolation layer covering the second contact via are formed. Thus, the risk of metal shorting is decreased.

In some embodiments, which can be combined with one or more previous embodiments, the first level metal layer is connected to the lateral contact through the second contact via. Thus, the lateral contact is connected to the BEOL through the first level metal layer.

In some embodiments, which can be combined with one or more previous embodiments, a gate contact via, a third isolation layer covering the gate contact via, a first and second contact metallization, and a gate contact via metallization are formed. A portion of the third isolation layer is connected to the lateral contact. Thus, the risk of gate contact via-lateral contact is decreased.

In some embodiments, which can be combined with one or more previous embodiments, the second contact has a larger height than the first contact. This ensures that the second source/drain region, which is located at the bottom of the semiconductor device, is connected to the BEOL.

In some embodiments, which can be combined with one or more previous embodiments, a first transistor is formed that is stacked over a second transistor. The first and second source/drain regions are located on the first and the second transistors, respectively. Thus, the semiconductor device can be used in stacked semiconductor applications.

In some embodiments, which can be combined with one or more previous embodiments, a location of the second via is offset from a centerline of the second source/drain region away from a gate region. Thus, the risk of metal shorting is decreased.

In some embodiments, which can be combined with one or more previous embodiments, a horizontally extended portion over the second source/drain region, and a vertically extended portion connecting the horizontally extended portion to the lateral contact are formed. The vertically extended portion includes a smaller thickness compared to the horizontally extended portion. Thus, the second contact requires less space, which can decrease the risk of shorting.

According to yet another embodiment, a semiconductor device includes a source/drain via connecting a source/drain region to a back end of line (BEOL), and a gate via connecting a gate region to the BEOL. The gate via and the source/drain via are isolated from direct contact with the lateral contact through a first and a second dielectric isolation layer formed over the source/drain via and the gate via, respectively. Thus, both the source/drain region and the gate region are connected to the BEOL.

The concepts herein relate to stacked field-effect transistor (FET), which are fundamental electronic devices that have revolutionized the field of electronics and how various elements of the transistors are electrically connected. The stacked FET is a type of transistor architecture that offers improved functionality and benefits in integrated circuit (IC) design. The stacked FET involves stacking multiple FETs on top of each other, allowing for enhanced performance and increased integration density.

Pin access refers to the method or ability to access individual FETs in the stacked FET, for example, for testing or debugging purposes. The series arrangement of stacked FETs can make it difficult to interact with individual FETs. Unlike standard configuration, in a typical stacked FET, the first level metal layer, M1 track, for the bottom source/drain can be very limited, due to the shadowing effect of the top source/drain.

Recently, using local interconnects in a stacked FET configuration has attracted attention. However, using local interconnects also presents challenges. These challenges include the increased complexity of the design and fabrication process, the potential for signal integrity issues due to the close proximity of the interconnects, and the possibility of local interconnect shorting to nearby contact structures, especially gate contact over active regions.

To tackle the above-mentioned problems, disclosed is a semiconductor device with stacked FETs that utilize a local interconnect (“a lateral contact” hereinafter) and gate and source/drain contact vias that avoid source/drain contact-lateral contact shorting. To that end, the contact via and the source/drain vias are isolated from each other by an isolation layer. Such electrically isolated vias ensure that contact-to-contact shorting is avoided.

Accordingly, the teachings herein provide methods and systems of semiconductor device formation with lateral contact. The techniques described herein may be implemented in a number of ways. Example implementations are provided below with reference to the following figures.

Example Semiconductor Device with Lateral Contact Structure

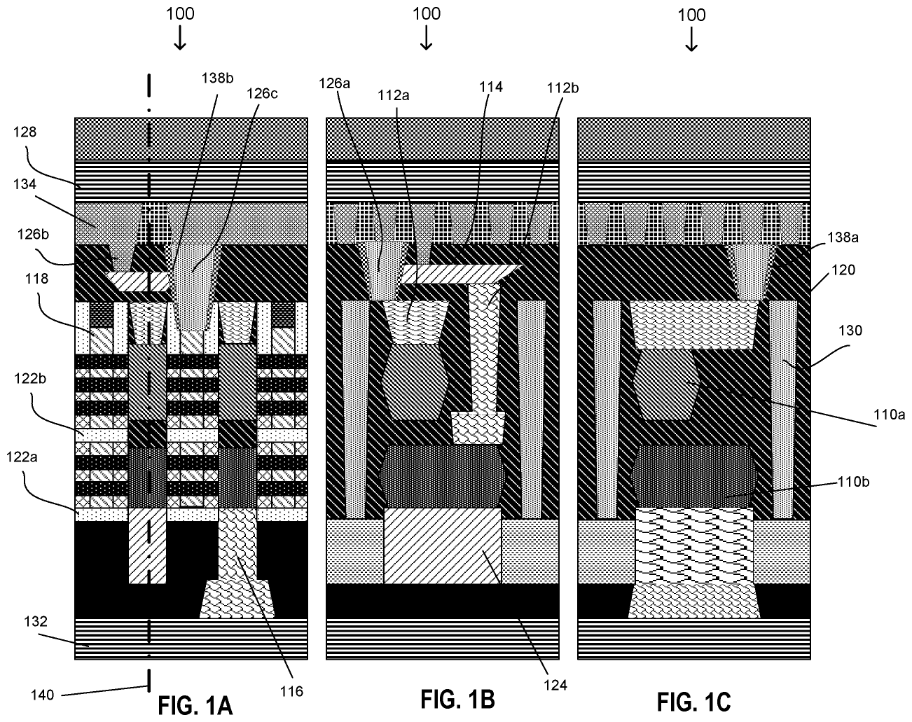

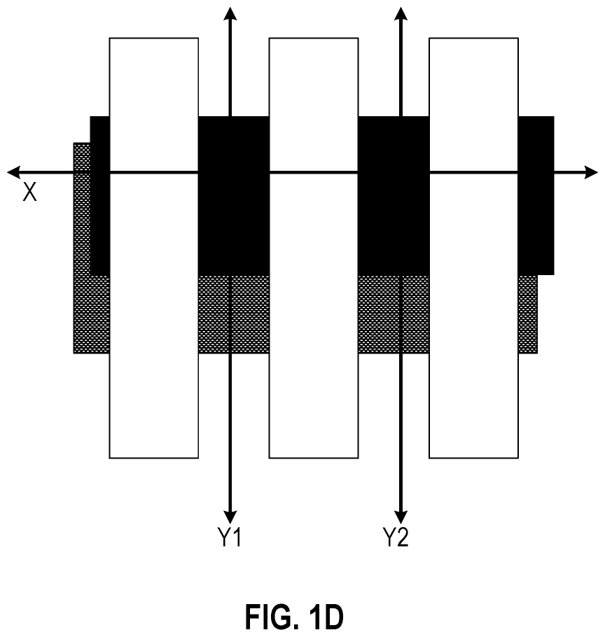

Reference now is made to FIGS. 1A-1C, which are simplified cross-section views of a semiconductor device 100, consistent with an illustrative embodiment. FIG. 1D depicts a top view of the semiconductor device 100. For example, FIG. 1A, and other figures denoted by A, illustrate an X section of the semiconductor device, FIG. 1B, and other figures denoted by B, illustrate a Y1 section of the semiconductor device and FIG. 1C, and other figures denoted by C, illustrate a Y2 section of the semiconductor device.

In various embodiments, the semiconductor device 100 is a stacked FET that leverages the vertical dimension of the semiconductor device 100 to increase the number of active devices within a given area. This way, instead of relying solely on lateral scaling, where semiconductor devices are shrunk in size on the semiconductor substrate, stacking FETs vertically can enable the incorporation of multiple layers of semiconductor devices. This arrangement enables more complex circuitry and advanced functionality.

In several embodiments, the stacked FET structure of the semiconductor device 100 can enable higher integration densities by utilizing the vertical dimension of the semiconductor device 100. In such embodiments, instead of relying solely on lateral scaling, which has its limits, stacking FETs on the semiconductor device 100 allows for increased transistor count within a given chip area. This increased transistor count enables the integration of more complex circuits, larger memory arrays, and other functional blocks, enhancing the capabilities of the semiconductor device 100.

The disclosed semiconductor device 100 can include first and second source/drain regions 110a and 110b, a first contact 112a, a second contact 112b, a lateral contact 114, a backside contact, BSCA, 116, a gate region 118, an interlayer dielectric, ILD, 120, a bottom dielectric isolation, BDI, 122a, a middle dialectic isolation, MDI, 122b, a placeholder 124, a first via 126a, a second via 126b, a gate via 126c, a back end of line, BEOL, 128, one or more gate cut regions 130, a backside interconnect 132, and a first level metal layer, M1 track, 134.

In several embodiments, the first source/drain region 110a is located on a first transistor, and the second source/drain region 110b is located on a second transistor. In such an embodiment, the first transistor is stacked over the second transistor.

Generally, the first and second source/drain regions 110a and 110b are two salient components that play relevant roles in the semiconductor device's operation. In various embodiments, the first and second source/drain regions 110a and 110b are regions within the semiconductor material, e.g., the semiconductor device 100, where the current flows in and out of the semiconductor device 100. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region. In some embodiments, the first source/drain region 110a is located on a first transistor, and the second source/drain region 110b is located on a second transistor. The first transistor can be stacked on top of the second transistor to form the semiconductor device 100.

The first contact 112a, located over the first source/drain region 110a, establishes a connection between the first source/drain region 110a and the BEOL 128. The first contact 112a ensures efficient electrical routing and connectivity within the semiconductor device 100. The fabrication of the first contact 112a can involve lithography and etching processes to define the contact area. The first contact 112a can be made using conductive materials such as a silicide liner, e.g., Ni, Ti, NiPt, an adhesion metal layer, e.g., TiN and conductive metal fill material, e.g., tungsten (W), Co, or Ru.

The second contact 112b, located over the second source/drain region 110b, establishes a connection between the second source/drain region 110b and the lateral contact 114. The second contact 112b ensures efficient electrical routing and connectivity within the semiconductor device 100. The fabrication of the second contact 112b can involve lithography and etching processes to define the contact area. The second contact 112b can be made using conductive materials such as a silicide liner, e.g., Ni, Ti, NiPt, an adhesion metal layer, e.g., TiN and conductive metal fill material, e.g., tungsten (W), Co, or Ru.

The lateral contact 114 can create a conducting path or link within the semiconductor device 100 to connect the second source/drain region 110b to the first level metal layer, i.e., the M1 tracks, which is shadowed by the first source/drain region 110a. Such a connection can improve routing flexibility. Without lateral contact 114, the second source/drain region 110b can only access the first level metal layer, M1 track 134, directly over the second contact 112b. In some embodiments, the lateral contact 114 is located above the first and second source/drain regions 110a and 110b. In an embodiment, as shown in FIG. 1A, the location of the lateral contact 114 can be offset from a centerline 140 of the second source/drain region 110b away from the gate region 118.

The BSCA 116 is a region on the backside of the semiconductor device 100 where electrical connections are made. By establishing the electrical contacts, the BSCA 116 ensures the proper functioning of the semiconductor device 100 and facilitates electrical signal transmission.

The BSCA 116 can serve as a thermal interface between the semiconductor device 100 and a heat sink or other cooling mechanisms. By establishing direct contact with the substrate, the BSCA 116 can conduct the heat away from the semiconductor device 100, and contribute to improved thermal dissipation. In some embodiments, the BSCA 116 can help mitigate parasitic effects, such as substrate coupling or substrate noise, from the semiconductor device 100. In further embodiments, the BSCA 116 can allow for increased integration density in the semiconductor device 100. In an embodiment, the BSCA 116 connects, i.e., wires, the second source/drain region 110b to the backside interconnect.

In various embodiments, the gate region 118 serves as control elements that regulate the flow of current through the semiconductor device 100. The gate region 118 can be composed of a conductive material. The gate region 118 can control the flow of electric current between the source and drain regions. In some embodiments, by applying a voltage to the gate, the channel region's conductivity is modulated, allowing the semiconductor device 100 to either allow or block the flow of current, which in turn enables the semiconductor device 100 to act as electronic switches or amplifiers. The gate voltage can determine whether the semiconductor device 100 is in an “on” or “off” state. When the gate voltage is below a certain threshold, the semiconductor device 100 is in the “off” state, and the current flow between the source and drain is effectively blocked. On the other hand, when the gate voltage exceeds the threshold, the semiconductor device 100 enters the “on” state, allowing current to flow through the channel region. In addition to acting as a switch, modulating the gate voltage can enable the gate region 118 to control the current flowing through the channel region, resulting in amplified output signals.

In an embodiment, the gate region 118 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate region 118, along with other semiconductor device components, can facilitate the miniaturization and integration of electronic circuits. The ability to control the channel region's conductivity through the gate voltage allows for compact and highly efficient circuit designs.

The ILD 120 can be a layer of insulating material to electrically isolate and provide mechanical support between different layers of conducting and active components. The ILD 120 can enable efficient signal transmission, reduce crosstalk, and ensure the proper functioning of the semiconductor device 100. In an embodiment, the ILD 120 can electrically isolate adjacent conducting layers or active components in the semiconductor device 100. By providing insulation between different layers, the ILD 120 can prevent electrical shorts, reduce (e.g., minimize) leakage current, and ensure that signals are directed only along the desired pathways. In some embodiments, the ILD 120 can help reduce parasitic capacitance between adjacent metal interconnects or active devices and provide mechanical support to the semiconductor device's structure.

The BDI 122a can electrically isolate individual components in the semiconductor device 100, and provide electrical isolation between each of the FETs in the stacked FET. That is, the BDI 122a can ensure that the operation of one component does not interfere with the operation of the others. By using a dielectric layer, which is an insulating layer that does not conduct electricity, the BDI 122a effectively prevents electrical crosstalk between different components and allows each one to operate independently. Further, by electrically isolating each transistor from the other, the BDI 122a can reduce the potential for crosstalk, which is the unwanted transfer of signals between circuit elements, thereby improving the overall performance of the semiconductor device 100.

By isolating each transistor, BDI 122a helps to prevent the failure of one transistor from affecting the others. This can improve the overall reliability of the device. Additionally, the BDI 122a allows for more flexibility in device design, as it allows each transistor in the stack to be accessed and controlled independently. This can be beneficial in a variety of applications where specific transistors may need to be activated or deactivated based on certain conditions. In some embodiments, the BDI 122a can help decrease the parasitic capacitance associated with the transistor, which can lead to faster switching times and improved performance.

The MDI 122b, similar to the BDI 122a, can electrically isolate individual components in the semiconductor device 100, and provide electrical isolation between each of the FETs in the stacked FET. That is, the MDI 122b can ensure that the operation of one component does not interfere with the operation of the others. By using a dielectric layer, which is an insulating layer that does not conduct electricity, the MDI 122b effectively prevents electrical crosstalk between the transistors and allows each one to operate independently. Further, by electrically isolating each transistor from the other, the MDI 122b can reduce the potential for crosstalk, which is the unwanted transfer of signals between circuit elements, thereby improving the overall performance of the semiconductor device 100.

By isolating each transistor, MDI 122b helps to prevent the failure of one transistor from affecting the others. This can improve the overall reliability of the device. Additionally, the MDI 122b allows for more flexibility in device design, as it allows each transistor in the stack to be accessed and controlled independently. This can be beneficial in a variety of applications where specific transistors may need to be activated or deactivated based on certain conditions. In some embodiments, the MDI 122b can help decrease the parasitic capacitance associated with the transistor, which can lead to faster switching times and improved performance.

In some embodiments, a placeholder 124 can be epitaxially grown. The use of the placeholder 124 can provide more flexibility in the fabrication process, allowing for the creation of complex geometries or the integration of different types of materials.

The first via 126a establishes an electrical connection between the first source/drain region 110a and the BEOL 128 through the first contact 112a. Fabrication of the first via 126a can involve a series of processes, including at least one of lithography, etching, and deposition. The first via 126a can be formed using conductive materials such as an adhesion metal layer, e.g., TiN and conductive metal fill material, e.g., tungsten (W), Co, Cu, or Ru. The presence of the first via 126a enables improved (e.g., optimal) electrical connectivity, contributing to improved device performance and reduced power losses.

In several embodiments, the semiconductor device 100 can include a first isolation layer 138a. The first isolation layer 138a can cover the first via 126a. In such embodiments, a portion of the first isolation layer 138a is connected to the lateral contact 114. In other words, the first isolation layer 138a can isolate the first via 126a from direct contact with the lateral contact 114. Thus, the first isolation layer 138a can ensure that the lateral contact 114 and the first via 126a do not interfere with each other's operation. Additionally, the first isolation layer 138a can be a non-conductive, i.e., insulating, layer that can be made from materials such as silicon dioxide (SiO2) or silicon nitride (Si3N4). In various embodiments, the first isolation layer 138a is a dielectric material.

In various embodiments, the first via 126a is connected to the BEOL 128 via the M1 track 134. In an embodiment, the M1 track can be used to connect various elements of the semiconductor device 100 to the BEOL 128.

The second via 126b connects the lateral contact 114 to the BEOL 128. The second via 126b can establish an electrical pathway between the lateral contact 114 and the BEOL 128. The fabrication of the second via 126b involves lithography, etching, and deposition processes similar to those used for the first via. The second via 126b can be formed using materials such as an adhesion metal layer, e.g., TiN and conductive metal fill material, e.g., tungsten (W), Cu, Co, or Ru.

Similarly, the gate via 126c can connect the gate region 118 to the BEOL 128. Similar to the first and second via 126a and 126b, the gate via 126c can be formed using conductive materials such as, an adhesion metal layer, e.g., TiN and conductive metal fill material, e.g., Cu, tungsten (W), Co, or Ru. In an embodiment, a second isolation layer 138b can cover the gate via 126c. In such an embodiment, a portion of the second isolation layer 138b is connected to the lateral contact 114. The second isolation layer 138b can isolate the gate via 126c from direct contact with the lateral contact 114. Thus, the second isolation layer 138b can ensure that the lateral contact 114 and the gate via 126c do not interfere with each other's operation. Additionally, the second isolation layer 138b can be a non-conductive, i.e., insulating, layer that can be made from materials such as silicon dioxide (SiO2) or silicon nitride (Si3N4). In various embodiments, the second isolation layer 138b is a dielectric. The first and second isolation layers 138a and 138b can be made of the same materials.

In some embodiments, the first and second isolation layers 138a and 138b provide electrical isolation between different components on the semiconductor device 100, prevent unwanted current flow between different parts of the semiconductor device 100 and help reduce crosstalk or interference. Thus, the first and second isolation layers 138a and 138b can facilitate the proper functioning of each individual component by maintaining the integrity and stability of their individual operations.

The semiconductor device's functionality can rely on the combination of the first via 126a, the second via 126b, the gate via 126c, the first contact 112a, the second contact 112b, and the lateral contact 114. These elements collectively enable efficient electrical connectivity between the first and second source/drain regions 110a and 110b and the BEOL 128. The semiconductor device 100 can benefit from improved power distribution, reduced signal losses, and enhanced signal transmission efficiency.

Example Processes for Semiconductor Device with Lateral Contact Structures

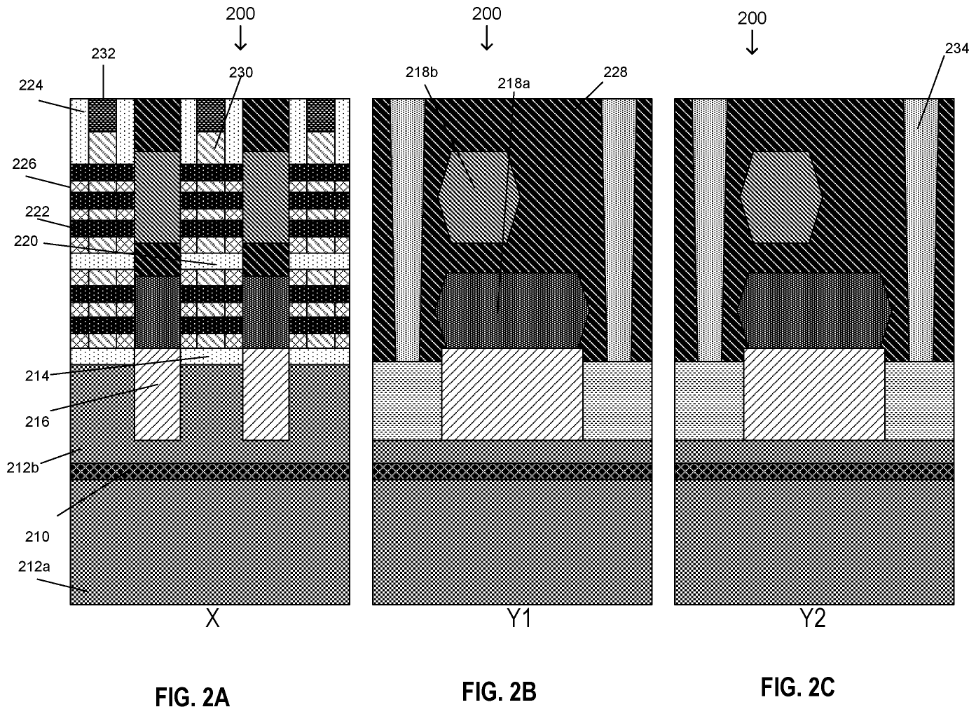

With the foregoing description of an example semiconductor device 200, it may be helpful to discuss an example process of manufacturing the same. To that end, FIGS. 2-11 illustrate various steps in the manufacture of a semiconductor device 200, consistent with illustrative embodiments. As noted above, figures denoted by A, B and C illustrate acts of fabrication of the semiconductor device 100 from a different point of view. It is also worth mentioning that the semiconductor device 100 depicted in FIGS. 1A-1C can be the same as the semiconductor device 200 depicted in FIGS. 2-11. For ease of illustration, the fabrication operations depicted therein will be described in the context of forming stacked transistors. The stacked transistors are fabricated to include a bottom transistor and a top transistor. The bottom transistor is fabricated to include a bottom source/drain region, and the top transistor is fabricated to include a top source/drain region.

Referring now is made to FIGS. 2A-2C, which illustrates a semiconductor device 200 after the processing of the front end of line (FEOL). Once the FEOL processing is performed, the semiconductor 200 can include an etch stop layer 210 between a first substrate 212a and a second substrate 212b, a bottom dielectric isolation, BDI, 214, placeholders 216, a bottom source/drain region 218a, a top source/drain region 218b, a middle dielectric isolation, MDI, 220, nanosheets gates 222, gate spacers 224, inner spacers 226, an interlayer dielectric, ILD, 228, gate regions 230, gate caps 232, and gate cut regions 234.

In the illustrative example depicted in FIGS. 2A-2C, the semiconductor device 200 is depicted as being on silicon as the first substrate 212a and the second substrate 212b, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first and second substrates 210a and 210b may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, an etch stop layer 210 is formed over the first substrate 212a. The etch stop layer 210 can be a thin layer of material incorporated into the structure of the semiconductor device 200 to provide a selective barrier against etching processes, preventing further removal of underlying materials during fabrication. The etch stop layer 210 can enable precise control over the etching depth and help define the desired device dimensions. The etch stop layer 210 can further provide a stopping point for the etching process, ensuring that specific layers or regions are not etched beyond a certain point, leading to accurate patterning and control of critical features. The etch stop layer 210 can create a distinct separation between different layers or components within the device structure, and prevent the undesired etching of underlying layers or materials, enabling the creation of complex, multi-layered structures with well-defined interfaces and boundaries. In some embodiments, the etch stop layer 210 acts as a protective barrier for sensitive or delicate materials to shield such materials from aggressive etchants, preventing damage or degradation during subsequent fabrication steps.

In some embodiments, prior to forming the etch stop layer 210, the first substrate 212a is prepared by cleaning and removing any impurities or oxide layers. The etch stop layer 210 is deposited onto the first substrate 212a using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 210 can then be selectively etched, stopping at a predetermined depth, while protecting the underlying layers. After the etching process, the remaining photoresist can be removed through stripping techniques. While in some embodiments, SiGe is used to form the etch stop layer 210, in some embodiments, silicon nitride (SiN) or silicon oxynitride (SiON) can be used as the etch stop layer 210. In some embodiments, a second substrate 212b is epitaxially grown over the etch stop layer 210.

In some embodiments, the nanosheets (e.g., nanosheet gates) 222 can be formed by alternating layers of Si and SiGe (not shown), in which sidewalls of the SiGe layers are indented and covered by the inner spacer 226. The SiGe layers can subsequently be removed and replaced with gate region materials.

The gate spacers 224 can be thin insulating layers or materials placed on the sidewalls of the gate regions 230 and the gate caps 232. The gate spacers 224 can help control the effective channel length of the semiconductor device 200. In various embodiments, the gate regions 230, and the gate caps 232, along with the gate spacers 224, can define the region where current flows between the bottom and top source/drain regions 218a and 218b.

In some embodiments, the gate spacers 224 can function as insulating layers between the gate regions 230 and the bottom and top source/drain regions 218a and 218b. That is, the gate spacers 224 can help prevent current leakage or short circuits between the gate regions 230 and the bottom and top source/drain regions 218a and 218b. Such isolation can help maintain the integrity of the semiconductor device's electrical operation and prevent unintended current flow that could negatively impact the performance of the semiconductor device 200 and reliability.

In further embodiments, the gate spacers 224 can be utilized to modulate the overlapping capacitance between the gate regions 230 and the bottom and top source/drain regions 218a and 218b. Overlapping capacitance can affect the semiconductor device's electrical characteristics, such as threshold voltage and switching behavior. Thus, by adjusting the thickness and material properties of the gate spacers 224, the overlapping capacitance can be optimized, which can allow for better control and modulation of the semiconductor device's behavior.

In several embodiments, the gate spacers 224 can help mitigate the short-channel effects by physically separating the gate regions 230 from the bottom and top source/drain regions 218a and 218b. To that end, the gate spacers 224 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability. In some embodiments, the bottom and top source/drain regions 218a and 218b are isolated from the gate caps 232 by the gate spacers 224.

In an embodiment, the gate spacers 224 can serve as barriers that prevent the lateral diffusion of dopant atoms from the bottom and top source/drain regions 218a and 218b, into the channel region during the doping process. Such diffusion can alter the channel characteristics and compromise the semiconductor device's performance. By confining the dopant diffusion, the gate spacers 224 can contribute to maintaining the desired semiconductor device's characteristics and electrical behavior.

In some embodiments, the gate spacers 224 can be formed over the sidewalls of the gate regions 230. The gate spacers 224 can be formed by deposition techniques. Alternatively, the gate spacers 224 can be formed by etching or selectively epitaxially growing the gate spacers 224 over the sidewalls of the gate regions 230. In some embodiments, the gate spacers 224 can include SiGe.

In an embodiment, the inner gate spacers 226, similar to the gate spacers 224, can function as insulating layers between the gate regions 230 and the bottom and top source/drain regions 218a and 218b. In various embodiments, the inner gate spacers 226 can be the same as the gate spacers 224, which are formed over portions of the gate regions 230 confined between the nanosheet gates 222.

The ILD 228 can be deposited onto the substrate using various techniques such as CVD, spin-on deposition, plasma-enhanced CVD (PECVD), or ALD. In some embodiments, after deposition, planarization techniques are employed to ensure a flat and smooth surface. In an embodiment, chemical mechanical polishing (CMP) can be used to remove excess material and achieve a uniform surface topography. In some embodiments, silicon dioxide (SiO2), or a low-k dielectric, e.g., organosilicates, fluorinated silicates, or porous materials, can be used as ILD 228. Alternatively, polymer-based materials, such as polyimide or polybenzoxazole (PBO), can be used as ILD 228.

The gate caps 232 can be formed over a plurality of gate regions. In some embodiments, the gate caps 232 can be made of the same materials as the gate spacers 224 and the inner gate spacers 226.

In some embodiments, the gate region 230 can include a thin layer of gate dielectric and gate metals (not shown). The gate metal can be separated from the gate channel by the gate dielectric, such as SiO2, HfO2, or HfLaOX.

The gate cut regions 234 form areas where the gate regions 230 are removed to create a non-continuous gate across the semiconductor device 200, segmenting it into individual FET units in the stack. In some embodiments, the gate cut regions 234 can physically disconnect these continuous gate regions 230, enabling independent control over each of the FETs within the stack. The gate cut regions 234 can help in reducing crosstalk between individual FETs in the stack, enhancing the overall semiconductor device 200 performance. Further, by isolating each FET in the stack, the gate cut regions 234 can prevent the failure of one transistor from affecting the others, thereby improving the overall reliability of the semiconductor device 200. In an embodiment, the gate cut regions 234 provides flexibility in the semiconductor device design, by allowing for the individual FETs within the stack to be accessed and controlled independently, which can be advantageous in custom circuit design. In some embodiments, the use of gate cut regions 234 can allow for fine-tuning of the semiconductor device's characteristics post-fabrication, as different gate voltages can be applied to different FETs in the stack.

In various embodiments, the first dielectric isolation layer is formed through techniques such as Chemical Vapor Deposition (CVD) or Atomic Layer Deposition (ALD) to deposit the first isolation dielectric layer.

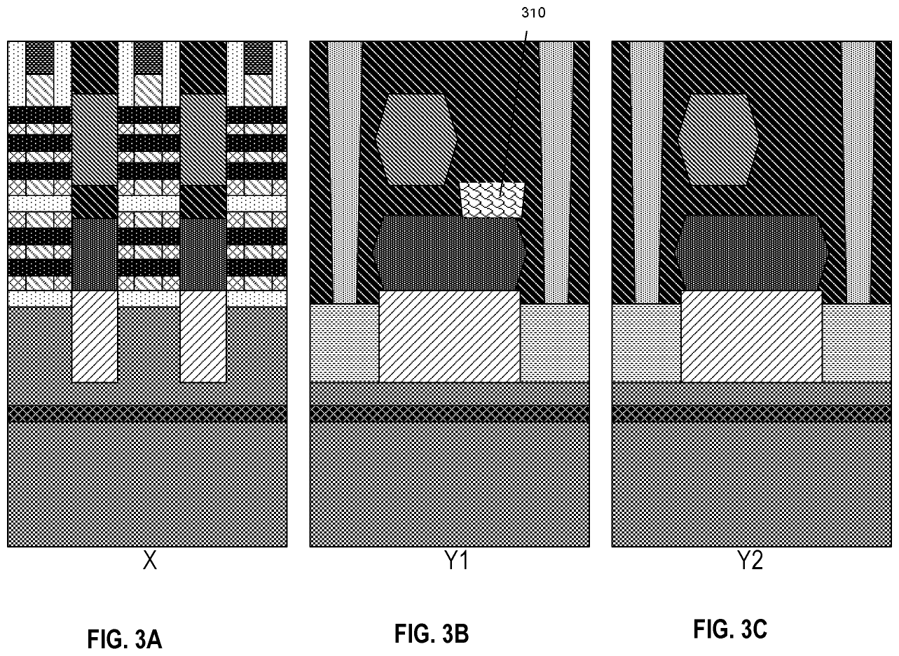

FIGS. 3A-3C illustrate side-views of a semiconductor device after the formation of a contact over the bottom source/drain region, in accordance with some embodiments. In an embodiment, a contact 310 can be formed over the bottom source/drain region. The contact 310 can be recessed, after chemical mechanical polishing (CMP) is performed.

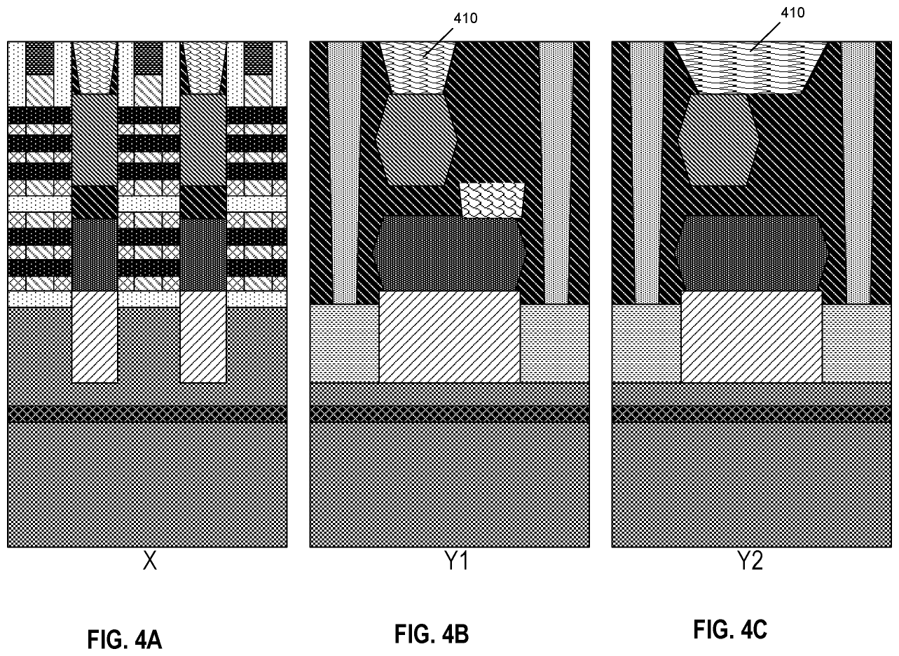

FIGS. 4A-4C illustrate side-views of a semiconductor device after the patterning of a contact area for the top source/drain region, in accordance with some embodiments. In an embodiment, a portion of the ILD over the top source/drain region is removed to form a cavity. The contact area for the top source/drain region 410 is subsequently formed over the top source/drain region by metallization of the cavity by a proper metal.

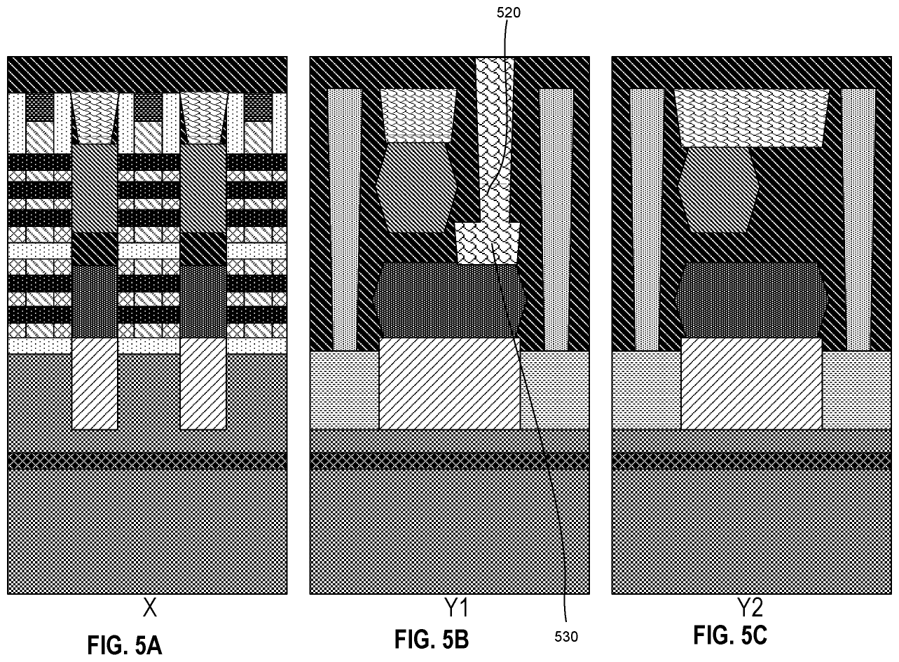

FIGS. 5A-5C illustrate side-views of a semiconductor device after the formation of a deep contact area for the bottom source/drain region, in accordance with some embodiments. In an embodiment, a first additional layer of ILD can be formed over the top surface of the semiconductor device 200 to cover the entire surface of the semiconductor device 200.

Portions of the first additional layer of ILD can be removed to form a cavity extending from the top surface of the semiconductor device 200 to the top surface of the contact over the bottom source/drain region.

In some embodiments, the second contact can include a horizontally extended portion 520 and a vertically extended portion 530. The horizontally extended portion 520 can be located over the second source/drain region, and the vertically extended portion 530 can connect the horizontally extended portion 520 to the lateral contact. In additional embodiments, the vertically extended portion 530 is substantially taller, e.g., deeper, than the horizontally extended portion 520. The vertically extended portion 530 can then be formed by filling the cavity with a suitable material, to connect the contact over the bottom source/drain region, e.g., the horizontally extended portion 520, to the top of the first additional layer of ILD.

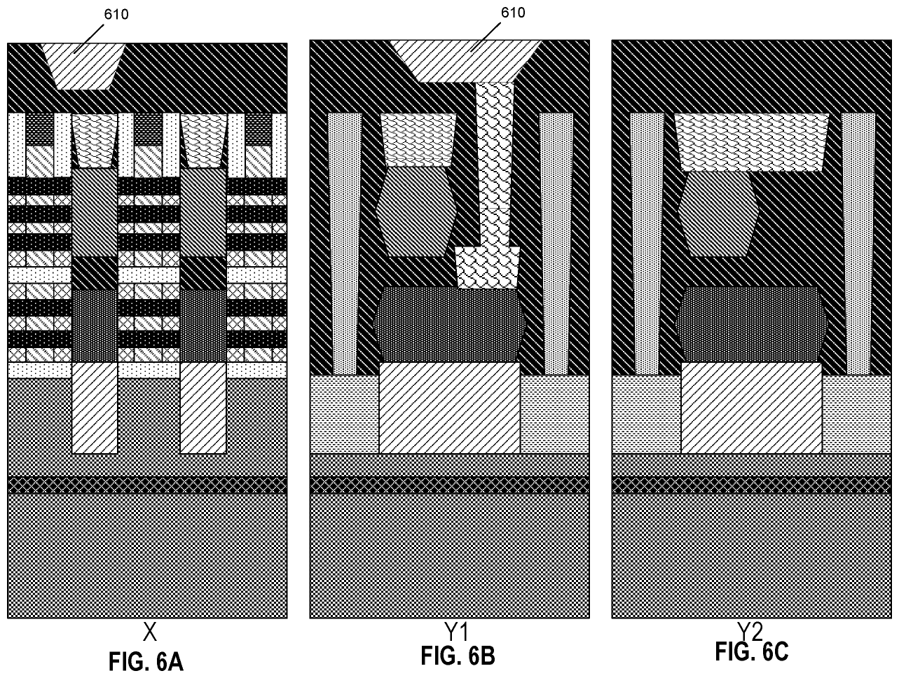

FIGS. 6A-6C illustrate side-views of a semiconductor device after the formation of a lateral contact, in accordance with some embodiments. In an embodiment, a second additional layer of ILD is formed over the semiconductor device 200. Portions of the second additional layer of ILD can be removed from the top surface of the semiconductor device 200 to reach the top surface of the deep contact area. In some embodiments, the removed portions of the second additional layer of ILD form an area that is substantially larger than the top surface of the deep contact area. Subsequently, the lateral contact 610 is formed within the removed portions of the second additional layer of ILD. Thus, the lateral contact 610 can connect the bottom source/drain region to the top surface of the semiconductor device 200 via the contact area over the bottom source/drain region and the deep contact area.

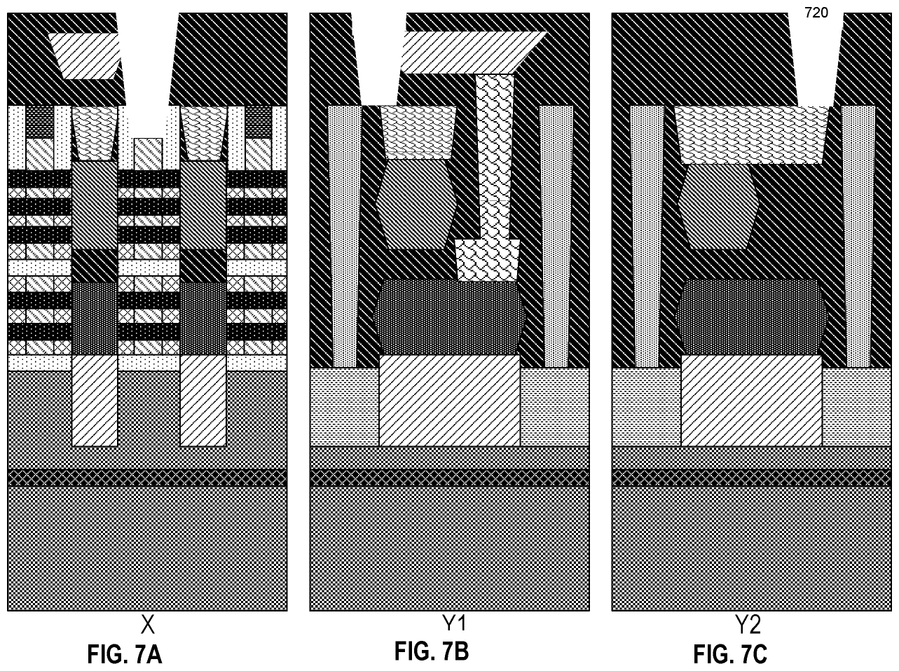

FIGS. 7A-7C illustrate side-views of a semiconductor device after the pattering of a gate via and a source/drain via, in accordance with some embodiments. In an embodiment, a third additional layer of ILD is formed over the top surface of the semiconductor device 200. Then, the first portions of the ILD layer are removed from the top surface of the semiconductor device 200 to reach the top of the gate regions. As a result, a first cavity 710 is formed over the gate region. Similarly, second portions of the ILD layer are removed from the top surface of the semiconductor device 200 to reach the top of the contact area for the top source/drain region. As a result, a second cavity 720 is formed over the contact area for the top source/drain region.

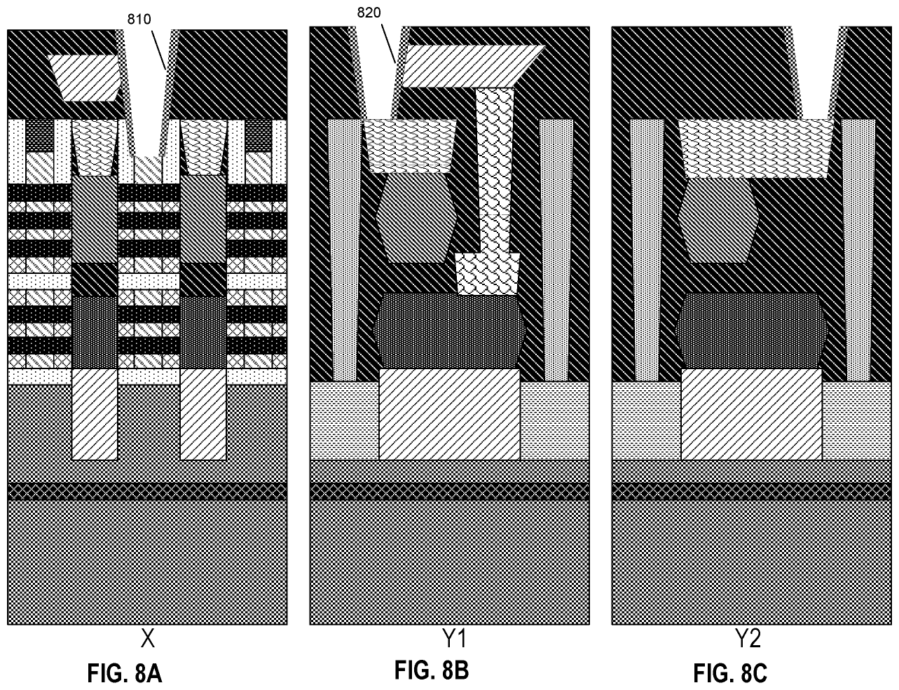

FIGS. 8A-8C illustrate side-views of a semiconductor device after the formation of spacers, in accordance with some embodiments. In an embodiment, a layer of spacer is formed on the sidewalls of the first and second cavities 810 and 820. The spacer can be an isolation material to isolate the cavities from the local interconnect, which is in contact with the cavities.

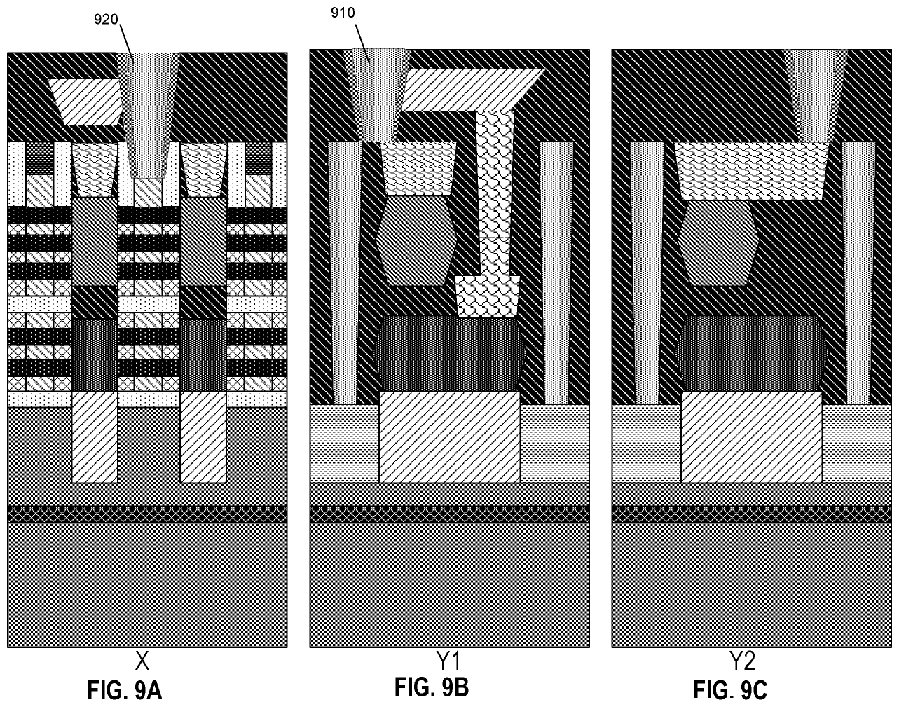

FIGS. 9A-9C illustrate side-views of a semiconductor device after the metallization of the gate and source/drain region vias, in accordance with some embodiments. In an embodiment, the first cavity and the second cavity are filled with suitable materials to form a first via 910 and a second via 920.

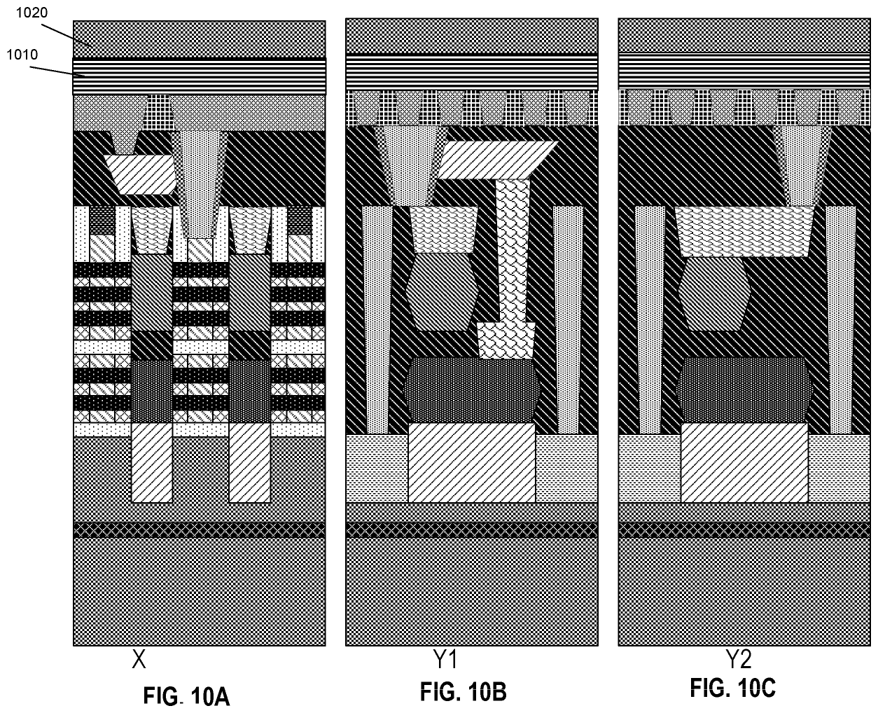

FIGS. 10A-10C illustrate side-views of a semiconductor device after the wafer bonding, in accordance with some embodiments. In some embodiments, the back end of line (BEOL) and wafer bonding are performed.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer 1410 can be deposited or transferred onto one or both semiconductor device surfaces, and the semiconductor devices can then be brought into contact and subjected to temperature and pressure to create a metallic bond 1420.

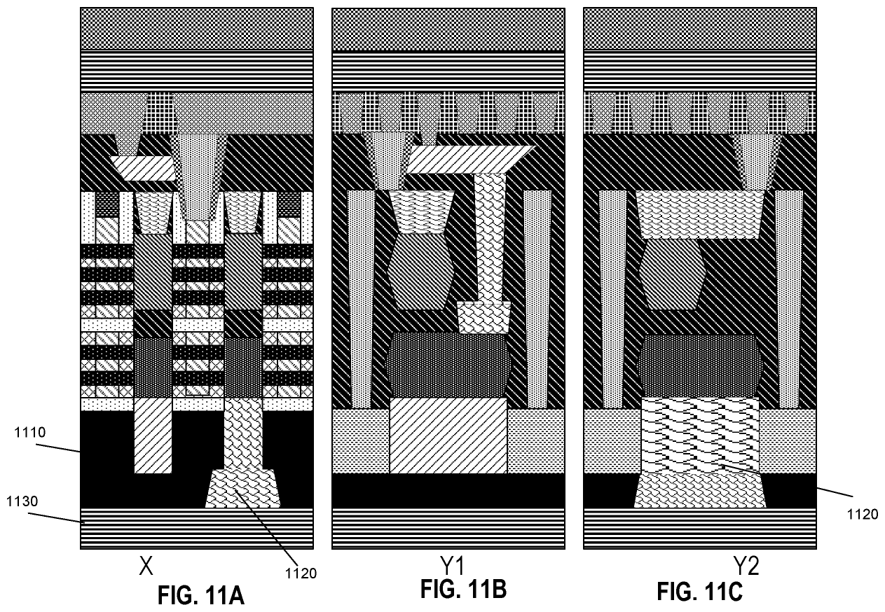

FIGS. 11A-11B illustrate side-views of a semiconductor device after the backside interconnect is patterned, in accordance with some embodiments. In some embodiments, the wafer is flipped, and the first substrate is removed. The first substrate removal process can proceed until reaching the etch stop layer. It should be noted that, for the sake of simplicity, the semiconductor device 200 is not shown are flipped. In some embodiments, the etch stop layer is removed, followed by removing the remaining substrate, i.e., the second substrate. The backside ILD, BILD, 1110 is formed below the BDI, and surrounds the placeholder, and the STI. In an embodiment, a CMP process is further processed after the formation of the BILD 1110.

The BILD 1110 can be an insulating material or layer used to isolate and provide electrical insulation between the semiconductor device's active regions and the BSCA 1120, and to prevent unwanted electrical contact between the active regions and the backside contact, ensuring the proper functioning and integrity of the semiconductor device 200. In various embodiments, the BILD 1110 can function as a protective layer, shielding the active regions of the semiconductor device 200 from external contaminants, moisture, and mechanical stress. The BILD 1110 can further help prevent physical damage, such as scratches or particle contamination, which could adversely affect semiconductor device performance. Additionally, the BILD 1110 can function as a barrier against moisture ingress, which can cause corrosion and degradation of the semiconductor device's components. In some embodiments, the placeholder can be removed so that a recess is formed that exposes the bottom of the first source/drain region. The BSCA 1120 is formed within the recess by filling with a metal contact. A backside interconnect 1130 is formed to cover the BSCA 1120 and the BILD 1110. The backside interconnect 1130 can be used to connect the semiconductor device 200 to other devices.

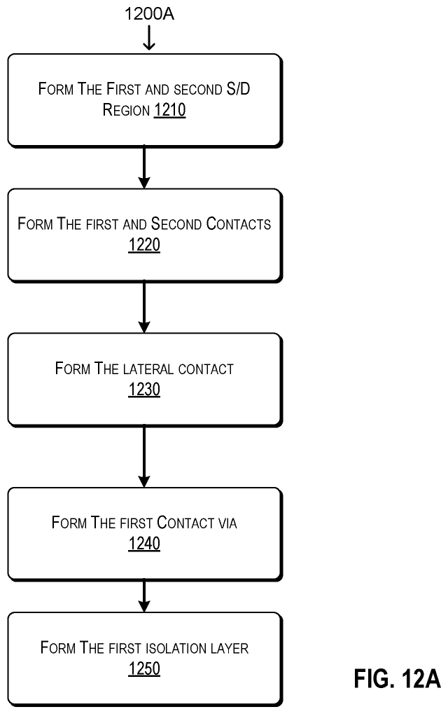

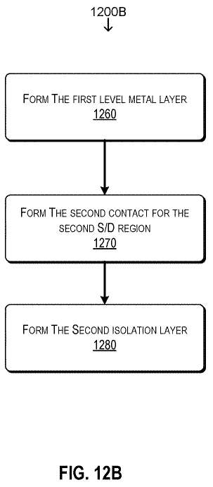

FIGS. 12A-12B illustrate block diagrams of a method 1200A for forming the semiconductor device, in accordance with some embodiments. Referring to FIG. 12A now, the method 1200A can begin when a first and a second source/drain regions are formed, as shown by block 1210. The first source/drain region can be part of a first transistor stacked over a second transistor, and the second source/drain region can be part of the second transistor.

In an embodiment, the method 1200A proceeds when a first and a second contact for the first and second source/drain regions are formed, as shown by block 1220. The second contact can include a horizontally extended portion over the second source/drain region, and a vertically extended portion connecting the horizontally extended portion to the lateral contact.

In some embodiments, the method 1200A continues when a lateral contact is formed, as shown by block 1230.

In some embodiments, the method 1200A continues when a first contact via for the first source/drain region is formed, as shown by block 1240.

In some embodiments, the method 1200A continues when a first isolation layer covering the first contact via is formed, as shown by block 1250. The first isolation layer can isolate the first via from direct contact with the lateral contact.

Referring to FIG. 12B now, a method 1200B for forming the semiconductor device, is shown. The method 1200B can begin when a first level metal layer is formed, as shown by block 1260.

The method 1200B can proceed when a second contact via for the second source/drain region is formed, as shown by block 1270.

The method 1200B can proceed when a second isolation layer is formed, as shown by block 1280. The second isolation layer can isolate the second via from direct contact with the lateral contact.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first source/drain region connected to a back end of line (BEOL) through a first contact and a first via; and
a second source/drain region connected to the BEOL through a second contact, a lateral contact and a second via, wherein the first via passes through the lateral contact, and wherein the first source/drain region is formed over the second source/drain region.

2. The semiconductor device of claim 1, wherein the lateral contact is located above the first and second source/drain regions.

3. The semiconductor device of claim 1, further comprising a first transistor stacked over a second transistor, wherein the first and second source/drain regions are located on the first and the second transistors, respectively.

4. The semiconductor device of claim 1, wherein the second contact further comprises:
a horizontally extended portion over the second source/drain region; and
a vertically extended portion connecting the horizontally extended portion to the lateral contact.

5. The semiconductor device of claim 1, further comprising a first isolation layer covering the first via, wherein a portion of the first isolation layer is connected to the lateral contact.

6. The semiconductor device of claim 5, wherein the first isolation layer isolates the first via from direct contact with the lateral contact.

7. The semiconductor device of claim 1, further comprising a gate via connecting a gate region to the BEOL.

8. The semiconductor device of claim 7, wherein a location of the second via is offset from a centerline of the second source/drain region away from the gate region.

9. The semiconductor device of claim 7, further comprising a second isolation layer covering the gate via, wherein the second isolation layer-covered gate via passes through the lateral contact and the first and second contacts.

10. The semiconductor device of claim 9, wherein the second isolation layer isolates the gate via from direct contact with the lateral contact.

11. A method for forming a semiconductor device, the method comprising:
forming a first and a second source/drain region;
forming a first and a second contact for the first and the second source/drain region, respectively;
forming a lateral contact over the second contact;
forming a first contact via for the first source/drain region; and
forming a first isolation layer covering the first contact via, wherein the first source/drain region is formed over the second source/drain region.

12. The method of claim 11, wherein the lateral contact is located above the first and second source/drain regions, and wherein the first isolation layer isolates the first contact via from direct contact with the lateral contact.

13. The method of claim 11, further comprising:
forming a first level metal layer;
forming a second contact via for the second source/drain region; and
forming a second isolation layer covering the second contact via.

14. The method of claim 13, wherein the first level metal layer is connected to the lateral contact through the second contact via.

15. The method of claim 11, further comprising:
forming a gate contact via;
forming a third isolation layer covering the gate contact via;
forming a first and second contact metallization; and
forming a gate contact via metallization, wherein a portion of the third isolation layer via is connected to the lateral contact.

16. The method of claim 11, wherein the second contact has a larger height than the first contact.

17. The method of claim 11, further comprising:
forming a first transistor stacked over a second transistor, wherein the first and second source/drain regions are located on the first and the second transistors, respectively.

18. The method of claim 17, wherein a location of the second via is offset from a centerline of the second source/drain region away from a gate region.

19. The method of claim 13, wherein forming the second contact comprises:
forming a horizontally extended portion over the second source/drain region; and
forming a vertically extended portion connecting the horizontally extended portion to the lateral contact.

20. A semiconductor device, comprising:
a source/drain via connecting a source/drain region to a back end of line (BEOL); and
a gate via connecting a gate region to the BEOL, wherein the gate via and the source/drain via are isolated from direct contact with a lateral contact through a first and a second dielectric isolation layer formed over the source/drain via and the gate via, respectively.
